(19) United States
(12) Patent Application Publication
(10) Pub. No.: US 2026/0204216 A1
(43) Pub. Date: Jul. 16, 2026

(54) DISPLAY PANEL, DISPLAY APPARATUS INCLUDING THE SAME AND ELECTRONIC APPARATUS INCLUDING THE SAME

(71) Applicant: SAMSUNG DISPLAY CO., LTD., YONGIN-SI (KR)

(72) Inventors: SEONGKYU LEE, Yongin-si (KR); JONGSIK SHIM, Yongin-si (KR)

(21) Appl. No.: 19/346,925

(22) Filed: Oct. 1, 2025

(30) Foreign Application Priority Data
Jan. 16, 2025 (KR) 10-2025-0006549

(51) Int. Cl. G09G 3/3233; H10D 86/40; H10D 86/60

(52) U.S. Cl. CPC G09G 3/3233; H10D 86/441; H10D 86/481; H10D 86/60; G09G 2300/0819; G09G 2300/0852; G09G 2300/0861; G09G 2310/08; G09G 2320/0233

(57) ABSTRACT

A display panel includes a first pixel and a second pixel disposed adjacent to the first pixel. The first pixel includes a light emitting element, a first transistor transmitting a driving current to the light emitting element, a first capacitor including a first electrode connected to the first node and a second electrode connected to the third node and a second capacitor including a first electrode connected to the third node and a second electrode receiving a first power voltage. The second pixel includes a light emitting element, a first transistor transmitting a driving current to the light emitting element, a first capacitor including a first electrode connected to the first node and a second electrode connected to the third node and a second capacitor including a first electrode connected to the third node and a second electrode receiving a voltage different from the first power voltage.

### CROSS-REFERENCE TO RELATED APPLICATION(S)

This application claims priority under 35 U.S.C. § 119 to and benefits from Korean Patent Application No. 10-2025-0006549 filed on Jan. 16, 2025 in the Korean Intellectual Property Office (KIPO), the entire disclosure of which is herein incorporated by reference.

### TECHNICAL FIELD

Embodiments of the disclosure relate to a display panel, a display apparatus including the display panel and an electronic apparatus including the display apparatus that enhances a display quality.

### DISCUSSION OF RELATED ART

Generally, a display apparatus includes a display panel and a display panel driver. The display panel includes multiple gate lines, multiple data lines, multiple emission lines, and multiple pixels. The display panel driver includes a gate driver, a data driver, an emission driver, and a driving controller. The gate driver outputs gate signals to the gate lines. The data driver outputs data voltages to the data lines. The emission driver outputs emission signals to the emission lines. The driving controller controls an operation of the gate driver, an operation of the data driver and an operation of the emission driver.

In a comparative display panel, first ends of hold capacitors of all pixels may be commonly connected to a high power voltage, which is a voltage providing power to an emission element. When a level of the high power voltage fluctuates due to noise, a level of a driving current of all pixels fluctuates so that a bright portion (when the noise increases the power voltage) and a dark portion (when the noise decreases the power voltage) may be generated in a unit of a horizontal line.

When the light portion and the dark portion are perceived by a user, a display defect may be perceived by a user.

### SUMMARY

Embodiments of the disclosure provide a display panel including a first pixel and a second pixel having different connections for hold capacitors, and accordingly prevent a change of a power voltage from being perceived by a user as a bright portion and a dark portion, thereby enhancing display quality.

Embodiments of the disclosure also provide a display apparatus including the display panel.

Embodiments of the disclosure also provide an electronic apparatus including the display apparatus.

In an embodiment of a display panel according to the disclosure, the display panel includes a first pixel and a second pixel disposed adjacent to the first pixel. The first pixel includes a light emitting element, a first transistor including a control electrode connected to a first node, a first electrode connected to a second node and a second electrode connected to a third node, the first transistor being configured to transmit a driving current to the light emitting element, a second transistor configured to apply a data voltage of the first pixel to the first node, a first capacitor including a first electrode connected to the first node and a second electrode connected to the third node and a second capacitor including a first electrode connected to the third node and a second electrode configured to receive a first power voltage. The second pixel includes a light emitting element, a first transistor including a control electrode connected to a first node, a first electrode connected to a second node and a second electrode connected to a third node, the first transistor being configured to transmit a driving current to the light emitting element, a second transistor configured to apply a data voltage of the second pixel to the first node, a first capacitor including a first electrode connected to the first node and a second electrode connected to the third node and a second capacitor including a first electrode connected to the third node and a second electrode configured to receive a voltage different from the first power voltage, the first power voltage is a driving voltage of each of the first pixel and the second pixel for generating the driving current.

In an embodiment, a second power voltage may be applied to a cathode electrode of the light emitting element of the first pixel and a cathode electrode of the light emitting element of the second pixel. The second power voltage may be applied to the second electrode of the second capacitor of the second pixel. The second power voltage may be a negative driving voltage of each of the first pixel and the second pixel.

In an embodiment, the first pixel may further include a third transistor configured to apply a reference voltage to the first node of the first pixel. The second pixel may further include a third transistor configured to apply the reference voltage to the first node of the second pixel.

In an embodiment, the reference voltage may be applied to the second electrode of the second capacitor of the second pixel.

In an embodiment, the first pixel may further include a fourth transistor configured to apply an initialization voltage to the light emitting element of the first pixel. The second pixel may further include a fourth transistor configured to apply the initialization voltage to the light emitting element of the second pixel.

In an embodiment, the initialization voltage may be applied to the second electrode of the second capacitor of the second pixel.

In an embodiment, the first pixel may further include a fifth transistor including a first electrode configured to receive the first power voltage and a second electrode connected to the second node of the first pixel and a sixth transistor including a first electrode connected to the third node of the first pixel and a second electrode connected to an anode electrode of the light emitting element of the first pixel. The second pixel may further include a fifth transistor including a first electrode configured to receive the first power voltage and a second electrode connected to the second node of the second pixel and a sixth transistor including a first electrode connected to the third node of the second pixel and a second electrode connected to an anode electrode of the light emitting element of the second pixel.

In an embodiment, the first transistor of the first pixel may further include a second control electrode connected to the third node of the first pixel.

In an embodiment, the first transistor of the second pixel may further include a second control electrode connected to the third node of the second pixel.

In an embodiment, the display panel may further include a gate line extending in a first direction, a data line extending in a second direction intersecting the first direction, and a plurality of first pixels and a plurality of second pixels alternately disposed in the first direction and in the second direction.

In an embodiment, the display panel may further include a gate line extending in a first direction, a data line extending in a second direction intersecting the first direction, and a plurality of first pixels and a plurality of second pixels alternately disposed in the first direction.

In an embodiment, the display panel may further include a gate line extending in a first direction, a data line extending in a second direction intersecting the first direction, and a plurality of first pixels and a plurality of second pixels alternately disposed in the second direction.

In an embodiment, a writing gate signal may be applied to a control electrode of the second transistor of the first pixel. The first pixel may further include a third transistor including a control electrode configured to receive a reference gate signal, a first electrode configured to receive a reference voltage and a second electrode connected to the first node of the first pixel, a fourth transistor including a control electrode configured to receive an initialization gate signal, a first electrode configured to receive an initialization voltage and a second electrode connected to an anode electrode of the light emitting element of the first pixel, a fifth transistor including a control electrode configured to receive a first emission signal, a first electrode configured to receive the first power voltage and a second electrode connected to the second node of the first pixel and a sixth transistor including a control electrode configured to receive a second emission signal, a first electrode connected to the third node of the first pixel and a second electrode connected to the anode electrode of the light emitting element of the first pixel.

In an embodiment, the writing gate signal may be applied to a control electrode of the second transistor of the second pixel. The second pixel may further include a third transistor including a control electrode configured to receive the reference gate signal, a first electrode configured to receive the reference voltage and a second electrode connected to the first node of the second pixel, a fourth transistor including a control electrode configured to receive the initialization gate signal, a first electrode configured to receive the initialization voltage and a second electrode connected to an anode electrode of the light emitting element of the second pixel, a fifth transistor including a control electrode configured to receive the first emission signal, a first electrode configured to receive the first power voltage and a second electrode connected to the second node of the second pixel and a sixth transistor including a control electrode configured to receive the second emission signal, a first electrode connected to the third node of the second pixel and a second electrode connected to the anode electrode of the light emitting element of the second pixel.

In an embodiment, the first emission signal may have an inactive level in a first period. The second emission signal may have an active level in the first period. The reference gate signal reference gate signal has an active level in the first period an active level in the first period. The initialization gate signal may have an active level in the first period. The writing gate signal may have an inactive level in the first period.

In an embodiment, the first emission signal may have an active level in a second period. The second emission signal may have an inactive level in the second period. The reference gate signal may have an active level in the second period. The initialization gate signal may have an active level in the second period. The writing gate signal may have an inactive level in the second period.

In an embodiment, the first emission signal may have an inactive level in a third period. The second emission signal may have an inactive level in the third period. The reference gate signal may have an inactive level in the third period. The initialization gate signal may have an active level in the third period. The writing gate signal may have an active level in the third period.

In an embodiment, the first emission signal may have an active level in a fourth period. The second emission signal may have an active level in the fourth period. The reference gate signal may have an inactive level in the fourth period. The initialization gate signal may have an inactive level in the fourth period. The writing gate signal may have an inactive level in the fourth period.

In an embodiment of a display apparatus according to the disclosure, the display apparatus includes a display panel, a gate driver and a data driver. The display panel includes a first pixel and a second pixel disposed adjacent to the first pixel. The gate driver is configured to output a gate signal to the first pixel and the second pixel. The data driver is configured to output a data voltage to the first pixel and the second pixel. The first pixel includes a light emitting element, a first transistor including a control electrode connected to a first node, a first electrode connected to a second node and a second electrode connected to a third node, the first transistor being configured to transmit a driving current to the light emitting element, a second transistor configured to apply a data voltage of the first pixel to the first node, a first capacitor including a first electrode connected to the first node and a second electrode connected to the third node and a second capacitor including a first electrode connected to the third node and a second electrode configured to receive a first power voltage. The second pixel includes a light emitting element, a first transistor including a control electrode connected to a first node, a first electrode connected to a second node and a second electrode connected to a third node, the first transistor being configured to transmit a driving current to the light emitting element, a second transistor configured to apply a data voltage of the second pixel to the first node, a first capacitor including a first electrode connected to the first node and a second electrode connected to the third node and a second capacitor including a first electrode connected to the third node and a second electrode configured to receive a voltage different from the first power voltage, the first power voltage is a driving voltage of each of the first pixel and the second pixel for generating the driving current.

In an embodiment of an electronic apparatus or electronic device according to the disclosure, the electronic apparatus includes a display panel, a gate driver, a data driver, a driving controller and a processor. The display panel includes a first pixel and a second pixel disposed adjacent to the first pixel. The gate driver is configured to output a gate signal to the first pixel and the second pixel. The data driver is configured to output a data voltage to the first pixel and the second pixel. The driving controller is configured to control the gate driver and the data driver. The processor is configured to output input image data and an input control signal to the driving controller. The first pixel includes a light emitting element, a first transistor including a control electrode connected to a first node, a first electrode connected to a second node and a second electrode connected to a third node, the first transistor being configured to transmit a driving current to the light emitting element, a second transistor configured to apply a data voltage of the first pixel to the first node, a first capacitor including a first electrode connected to the first node and a second electrode connected to the third node and a second capacitor including a first electrode connected to the third node and a second electrode configured to receive a first power voltage. The second pixel includes a light emitting element, a first transistor including a control electrode connected to a first node, a first electrode connected to a second node and a second electrode connected to a third node, the first transistor being configured to transmit a driving current to the light emitting element, a second transistor configured to apply a data voltage of the second pixel to the first node, a first capacitor including a first electrode connected to the first node and a second electrode connected to the third node and a second capacitor including a first electrode connected to the third node and a second electrode configured to receive a voltage different from the first power voltage, the first power voltage is a driving voltage of each of the first pixel and the second pixel for generating the driving current.

According to the display panel, the display apparatus including the display panel and the electronic apparatus including the display apparatus, the display panel may include a first type pixel (or ‘the first pixel’) and a second type pixel (or ‘the second pixel’) having different connection relations of the second capacitors and disposed adjacent to each other. A first power voltage may be applied to a second electrode of a second capacitor of the first type pixel. In contrast, a voltage different from the first power voltage may be applied to a second electrode of a second capacitor of the second type pixel.

For a case in which the first type pixel becomes a bright portion due to a change of the first power voltage, the second type pixel having the second capacitor receiving the voltage different from the first power voltage may become a dark portion compared to the first type pixel. For a case in which the first type pixel becomes a dark portion due to a change of the first power voltage, the second type pixel having the second capacitor receiving the voltage different from the first power voltage may become a bright portion compared to the first type pixel.

Thus, a luminance change of the first type pixel and a luminance change of the second type pixel may offset each other or a degree of visibility of the luminance change of the first type pixel may be reduced so that the bright portion and the dark portion may not be perceived by a user, and accordingly, the display quality of the display panel may be enhanced.

### BRIEF DESCRIPTION OF THE DRAWINGS

The above and other features and advantages of the disclosure will become more apparent by describing in detailed embodiments thereof with reference to the accompanying drawings, in which:

FIG. 1 is an example block diagram illustrating a display apparatus according to an embodiment of the disclosure;

FIG. 2 is an example diagram illustrating an arrangement of a first type pixel and a second type pixel of a display panel of FIG. 1;

FIG. 3 is an example diagram of an equivalent circuit illustrating the first type pixel of FIG. 2;

FIG. 4 is a timing diagram illustrating input signals applied to the first type pixel of FIG. 2;

FIG. 5 is an example diagram of an equivalent circuit illustrating an operation of the first type pixel of FIG. 2 in a first period;

FIG. 6 is a timing diagram illustrating input signals applied to the first type pixel of FIG. 2 in the first period;

FIG. 7 is an example diagram of an equivalent circuit illustrating an operation of the first type pixel of FIG. 2 in a second period;

FIG. 8 is a timing diagram illustrating input signals applied to the first type pixel of FIG. 2 in the second period;

FIG. 9 is an example diagram of an equivalent circuit illustrating an operation of the first type pixel of FIG. 2 in a third period;

FIG. 10 is a timing diagram illustrating input signals applied to the first type pixel of FIG. 2 in the third period;

FIG. 11 is an example diagram of an equivalent circuit illustrating an operation of the first type pixel of FIG. 2 in a fourth period;

FIG. 12 is an example timing diagram illustrating input signals applied to the first type pixel of FIG. 2 in the fourth period;

FIG. 13 is an example diagram of an equivalent circuit illustrating the second type pixel of FIG. 2;

FIG. 14 is a graph illustrating an example of a driving current of the first type pixel of FIG. 2 and an example of a driving current of the second type pixel of FIG. 2;

FIG. 15 is an example diagram illustrating an arrangement of a first type pixel and a second type pixel of a display panel of a display apparatus according to an embodiment of the disclosure;

FIG. 16 is an example diagram illustrating an arrangement of a first type pixel and a second type pixel of a display panel of a display apparatus according to an embodiment of the disclosure;

FIG. 17 is an example diagram of an equivalent circuit illustrating a second type pixel of a display panel of a display apparatus according to an embodiment of the disclosure;

FIG. 18 is an example diagram of an equivalent circuit illustrating a second type pixel of a display panel of a display apparatus according to an embodiment of the disclosure;

FIG. 19 is an example diagram of an equivalent circuit illustrating a first type pixel of a display panel of a display apparatus according to an embodiment of the disclosure;

FIG. 20 is an example diagram of an equivalent circuit illustrating a second type pixel of a display panel of a display apparatus according to an embodiment of the disclosure;

FIG. 21 is an example block diagram illustrating an electronic apparatus according to an embodiment of the disclosure;

FIG. 22 is a diagram illustrating an example in which the electronic apparatus of FIG. 21 is implemented as a smartphone; and

FIG. 23 is a diagram illustrating an example in which the electronic apparatus of FIG. 21 is implemented as a monitor.

### DETAILED DESCRIPTION OF THE EMBODIMENTS

Hereinafter, the disclosure will be explained in detail with reference to the accompanying drawings. While each drawing may represent one or more particular embodiments of the present disclosure, drawn to scale, such that the relative lengths, thicknesses, and angles can be inferred therefrom, it is to be understood that the disclosure is not necessarily limited to the relative lengths, thicknesses, and angles shown. Changes to these values may be made within the spirit and scope of the present disclosure, for example, to allow for manufacturing limitations and the like.

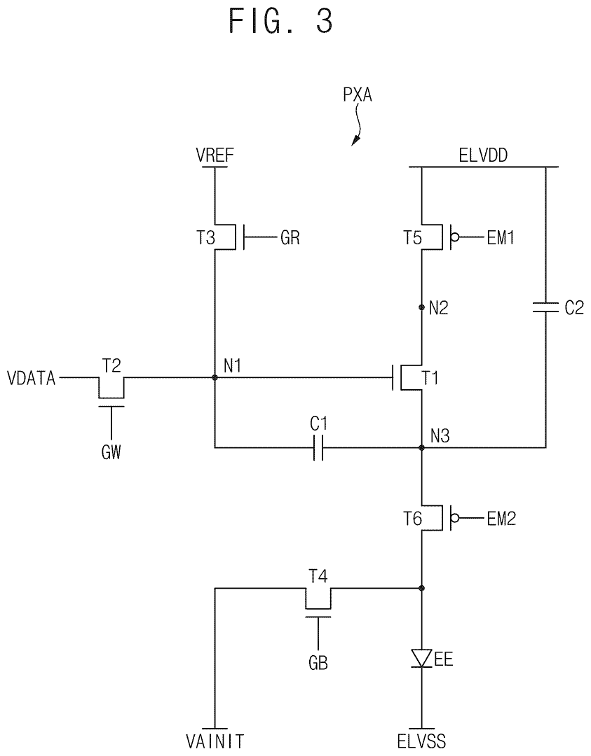

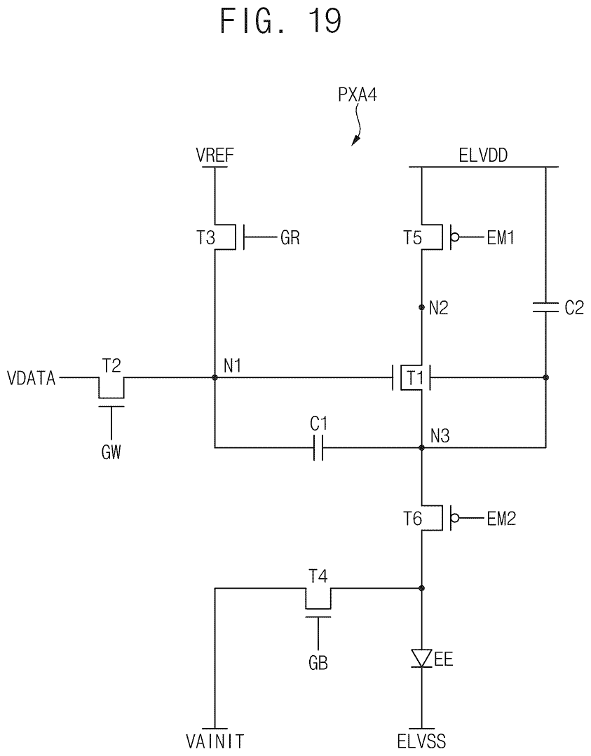

Embodiments of the disclosure relate to a display panel, a display device and an electronic apparatus that includes the same that eliminates an otherwise perceptible bright or dark spot or line on a display caused by fluctuations in a power supply voltage. This is achieved by designing two different pixel circuits PXA and PXB that are alternately arranged in one or both of a horizontal and vertical direction DR1 and DR2. A first of the two pixel circuits PXA has a hold (or ‘second’) capacitor C2 (see FIGS. 3 and 19) connected between a third node N3 and a first (or ‘high’) power voltage ELVDD. The third node N3 may correspond to a first electrode of a first (or ‘driving’) transistor T1 disposed between the light emitting element EE and the first transistor T1, and the first power voltage ELVDD may be a driving voltage of each of the first pixel and the second pixel for generating the driving current. In the second pixel PXB, the second capacitor C2 is connected between the third node N3 and another voltage source other than the first power voltage ELVDD. This other voltage may be the second power voltage ELVSS, an initialization voltage VAINIT or reference voltage VREF. By designing the two pixels PXA and PXB in an alternating manner, the bright and dark spots may be arranged in an alternating manner between individual pixels when a power source voltage fluctuates, as opposed to having entire lines or portions of lines being bright or dark when all of the pixel circuits are identical. As a result, the variation in illumination among the pixels due to the power source fluctuation is reduced or eliminated, such that the viewer no longer perceives bright and dark spots.

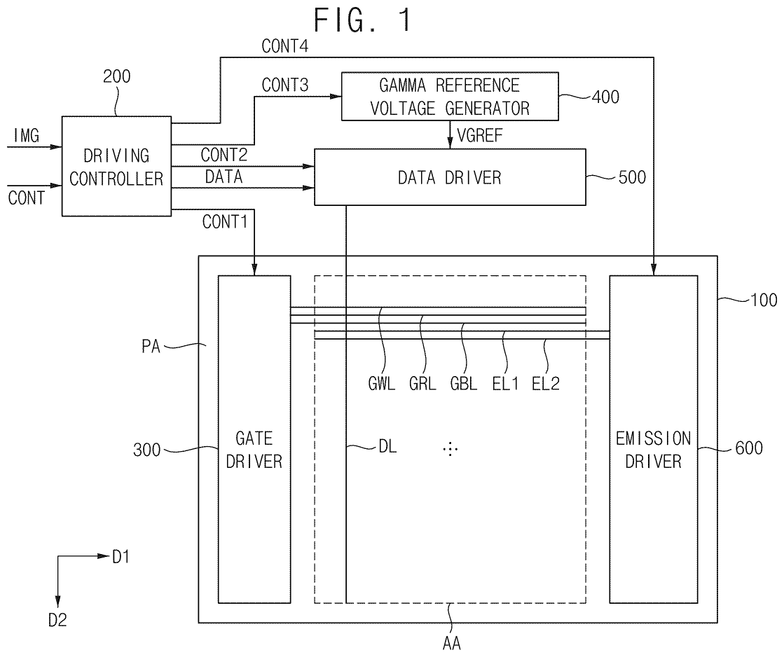

FIG. 1 is an example block diagram illustrating a display apparatus according to an embodiment of the disclosure.

Referring to FIG. 1, the display apparatus includes a display panel 100 and a display panel driver. The display panel driver includes a driving controller 200, a gate driver 300, a gamma reference voltage generator 400, a data driver 500 and an emission driver 600.

For example, the driving controller 200 and the data driver 500 may be a single, uninterrupted structure. For example, the driving controller 200, the gamma reference voltage generator 400 and the data driver 500 may be a single, uninterrupted structure. A driving module including at least the driving controller 200 and the data driver 500 may be referred to as a timing controller embedded data driver (TED).

The display panel 100 may have a display region AA on which an image is displayed and a peripheral region PA adjacent to the display region AA.

The display panel 100 may include multiple gate lines GWL, GRL and GBL, multiple data lines DL, multiple emission lines EL1 and EL2 and multiple pixels electrically connected to the gate lines GWL, GRL and GBL, the data lines DL and the emission lines EL1 and EL2. The gate lines GWL, GRL and GBL may extend in a first direction D1, the data lines DL may extend in a second direction D2 intersecting the first direction D1, and the emission lines EL1 and EL2 may extend in the first direction D1.

The driving controller 200 may receive input image data IMG and an input control signal CONT from an external apparatus (e.g., an application processor). For example, the driving controller 200 may receive the input image data IMG and the input control signal CONT from a host or an application processor. For example, the input image data IMG may include red image data, green image data and blue image data. The input image data IMG may include white image data. The input image data IMG may include magenta image data, cyan image data and yellow image data. The input control signal CONT may include a master clock signal and a data enable signal. The input control signal CONT may further include a vertical synchronizing signal and a horizontal synchronizing signal.

The driving controller 200 may generate a first control signal CONT1, a second control signal CONT2, a third control signal CONT3, a fourth control signal CONT4 and a data signal DATA based on the input image data IMG and the input control signal CONT.

The driving controller 200 may generate the first control signal CONT1 for controlling an operation of the gate driver 300 based on the input control signal CONT, and may output the first control signal CONT1 to the gate driver 300. The first control signal CONT1 may include a vertical start signal and a gate clock signal.

The driving controller 200 may generate the second control signal CONT2 for controlling an operation of the data driver 500 based on the input control signal CONT, and may output the second control signal CONT2 to the data driver 500. The second control signal CONT2 may include a horizontal start signal and a load signal.

The driving controller 200 may generate the data signal DATA based on the input image data IMG. The driving controller 200 may output the data signal DATA to the data driver 500.

The driving controller 200 may generate the third control signal CONT3 for controlling an operation of the gamma reference voltage generator 400 based on the input control signal CONT, and may output the third control signal CONT3 to the gamma reference voltage generator 400.

The driving controller 200 may generate the fourth control signal CONT4 for controlling an operation of the emission driver 600 based on the input control signal CONT, and may output the fourth control signal CONT4 to the emission driver 600.

The gate driver 300 may generate gate signals driving the gate lines GWL, GRL and GBL in response to the first control signal CONT1 received from the driving controller 200. The gate driver 300 may output the gate signals to the gate lines GWL, GRL and GBL. For example, the gate driver 300 may be integrated on the peripheral region PA of the display panel 100. For example, the gate driver 300 may be mounted on the peripheral region PA of the display panel 100.

The gamma reference voltage generator 400 may generate a gamma reference voltage VGREF in response to the third control signal CONT3 received from the driving controller 200. The gamma reference voltage generator 400 may provide the gamma reference voltage VGREF to the data driver 500.

In an embodiment, the gamma reference voltage generator 400 may be disposed in the driving controller 200 or in the data driver 500.

The data driver 500 may receive the second control signal CONT2 and the data signal DATA from the driving controller 200, and receive the gamma reference voltage VGREF from the gamma reference voltage generator 400. The data driver 500 may convert the data signal DATA into data voltages having an analog type using the gamma reference voltage VGREF. The data driver 500 may output the data voltages to the data lines DL.

The emission driver 600 may generate emission signals to drive the emission lines EL1 and EL2 in response to the fourth control signal CONT4 received from the driving controller 200. The emission driver 600 may output the emission signals to the emission lines EL1 and EL2. For example, the emission driver 600 may be integrated on the peripheral region PA of the display panel 100. For example, the emission driver 600 may be mounted on the peripheral region PA of the display panel 100.

Although the gate driver 300 is disposed at a first side of the display panel 100 and the emission driver 600 is disposed at a second side of the display panel 100 opposite to the first side in FIG. 1 for convenience of explanation, the disclosure might not necessarily be limited thereto. As another example, both of the gate driver 300 and the emission driver 600 may be disposed at the first side of the display panel 100. As another example, both of the gate driver 300 and the emission driver 600 may be disposed on both sides of the display panel 100. As another example, the gate driver 300 and the emission driver 600 may be a single, uninterrupted structure.

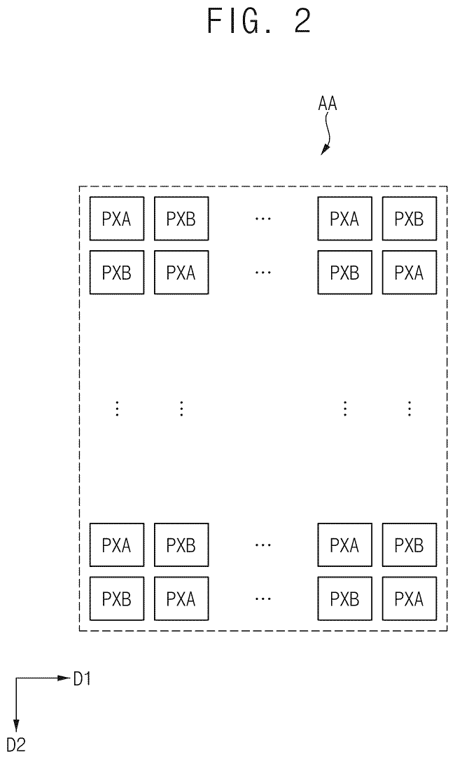

FIG. 2 is an example diagram illustrating an arrangement of a first type pixel PXA and a second type pixel PXB of the display panel 100 of FIG. 1.

Referring to FIGS. 1 and 2, the first type pixel PXA and the second type pixel PXB may be disposed adjacent to each other in the display area AA. The first type pixel PXA may be referred to as a first pixel. The second type pixel PXB may be referred to as a second pixel.

In the embodiment, the first type pixels PXA and the second type pixels PXB may be alternately disposed in the first direction D1 and the second direction D2.

In the embodiment, the first type pixels PXA and the second type pixels PXB may be alternately disposed in the first direction D1 and the second direction D2 so that a bright portion and a dark portion of the display panel 100 may not be perceived by a user.

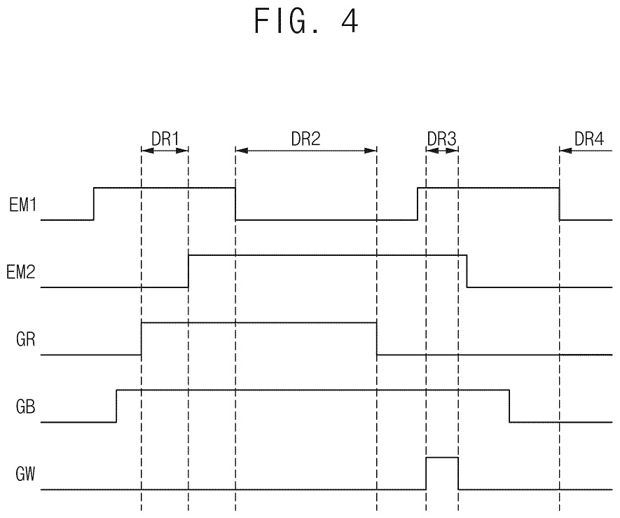

FIG. 3 is an example diagram of an equivalent circuit illustrating the first type pixel PXA of FIG. 2. FIG. 4 is a timing diagram illustrating input signals applied to the first type pixel PXA of FIG. 2.

Referring to FIGS. 1 to 4, the display panel 100 may include multiple pixels PXA and PXB. Each of the pixels PXA and PXB may include light emitting element EE. The pixels PXA and PXB may emit light based on a first power voltage ELVDD and a second power voltage ELVSS less than the first power voltage ELVDD.

The pixel PXA and PXB receives a writing gate signal GW, an initialization gate signal GB, a reference gate signal GR, the data voltage VDATA, a first emission signal EM1 and a second emission signal EM2; and the light emitting element EE may emit light according to a level of the data voltage VDATA to display an image.

The first type pixel PXA may include the light emitting element EE and a first transistor T1 applying a driving current to the light emitting element EE. Herein, the first transistor T1 may be an N-type transistor. The first transistor T1 may be an oxide semiconductor thin film transistor.

The driving current of the first type pixel PXA may be proportional to a square of a difference between the data voltage VDATA and a reference voltage VREF. The reference voltage VREF may be different from the first power voltage ELVDD. The reference voltage VREF may be different from the second power voltage ELVSS.

For example, the reference voltage VREF may be less than a white data voltage and greater than a black data voltage. For example, the reference voltage VREF may be less than the first power voltage ELVDD.

The first type pixel PXA may include the first transistor T1 including a control electrode connected to a first node N1, a first electrode connected to a second node N2 and a second electrode connected to a third node N3, a second transistor T2 including a control electrode receiving the writing gate signal GW, a first electrode receiving the data voltage VDATA and a second electrode connected to the first node N1, a third transistor T3 including a control electrode receiving the reference gate signal GR, a first electrode receiving the reference voltage VREF and a second electrode connected to the first node N1, a fourth transistor T4 including a control electrode receiving the initialization gate signal GB, a first electrode receiving an initialization voltage VAINIT and a second electrode connected to an anode electrode of the light emitting element EE, a fifth transistor T5 including a control electrode receiving the first emission signal EM1, a first electrode receiving the first power voltage ELVDD and a second electrode connected to the second node N2, a sixth transistor T6 including a control electrode receiving the second emission signal EM2, a first electrode connected to the third node N3 and a second electrode connected to the anode electrode of the light emitting element EE, the light emitting element EE including the anode electrode and a cathode electrode receiving the second power voltage ELVSS, a first capacitor C1 including a first electrode connected to the first node N1 and a second electrode connected to the third node N3 and a second capacitor C2 including a first electrode connected to the third node N3 and a second electrode receiving the first power voltage ELVDD.

In the embodiment, the second transistor T2, the third transistor T3 and the fourth transistor T4 may be N-type transistors. The second transistor T2, the third transistor T3 and the fourth transistor T4 may be oxide semiconductor thin film transistors.

In the embodiment, the fifth transistor T5 and the sixth transistor T6 may be P-type transistors. The fifth transistor T5 and the sixth transistor T6 may be low temperature polycrystalline silicon (“LTPS”) thin film transistors.

As another example, the fifth transistor T5 and the sixth transistor T6 may be N-type transistors.

As shown in FIG. 4, a driving timing of the pixel may include a first period DR1, a second period DR2, a third period DR3 and a fourth period DR4. The first period DR1 may be an initialization period. The second period DR2 may be a threshold voltage compensation period. The third period DR3 may be a writing period. The fourth period DR4 may be light emission period.

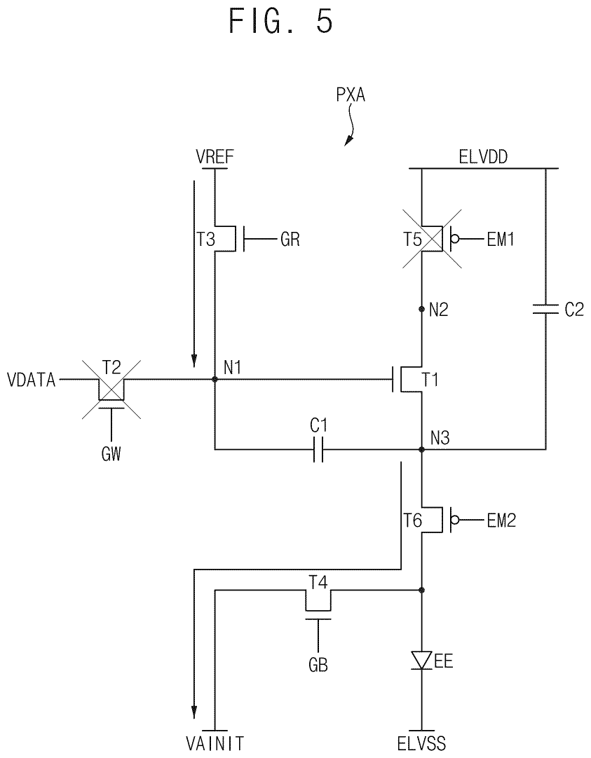

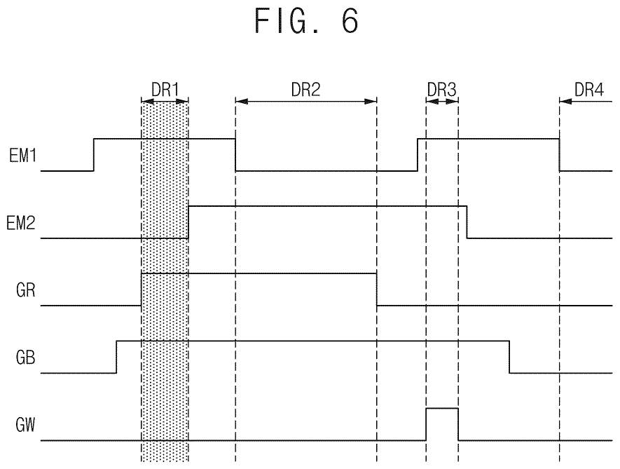

FIG. 5 is an example diagram of an equivalent circuit illustrating an operation of the first type pixel PXA of FIG. 2 in the first period DR1. FIG. 6 is a timing diagram illustrating the input signals applied to the first type pixel PXA of FIG. 2 in the first period DR1.

For a case in which the first emission signal EM1, the second emission signal EM2, the reference gate signal GR, the initialization gate signal GB and the writing gate signal GW are applied to P-type transistors, active levels of the first emission signal EM1, the second emission signal EM2, the reference gate signal GR, the initialization gate signal GB and the writing gate signal GW may be low levels; and inactive levels of the first emission signal EM1, the second emission signal EM2, the reference gate signal GR, the initialization gate signal GB and the writing gate signal GW may be high levels.

In contrast, for a case in which the first emission signal EM1, the second emission signal EM2, the reference gate signal GR, the initialization gate signal GB and the writing gate signal GW are applied to N-type transistors, active levels of the first emission signal EM1, the second emission signal EM2, the reference gate signal GR, the initialization gate signal GB and the writing gate signal GW may be high levels; and inactive levels of the first emission signal EM1, the second emission signal EM2, the reference gate signal GR, the initialization gate signal GB and the writing gate signal GW may be low levels.

Referring to FIGS. 1 to 6, in the first period DR1, the first emission signal EM1 may have an inactive level, the second emission signal EM2 may have an active level, the reference gate signal GR may have an active level, the initialization gate signal GB may have an active level and the writing gate signal GW may have an inactive level.

In the first period DR1, the second transistor T2 may be turned off, the third transistor T3 may be turned on, the fourth transistor T4 may be turned on, the fifth transistor T5 may be turned off and the sixth transistor T6 may be turned on.

In the first period DR1, the third transistor T3 may be tuned on so that the reference voltage VREF may be applied to the first node N1.

In the first period DR1, the fourth transistor T4 and the sixth transistor T6 may be turned on so that the initialization voltage VAINIT may be applied to the anode electrode of the light emitting element EE and the third node N3.

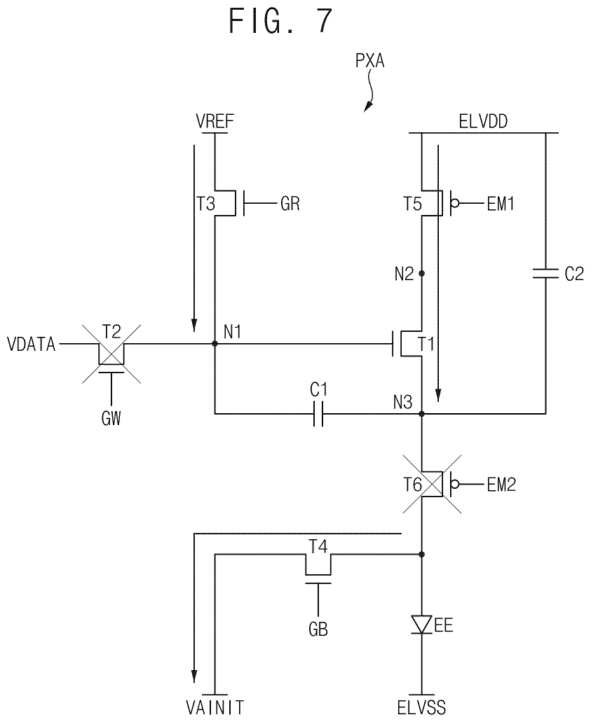

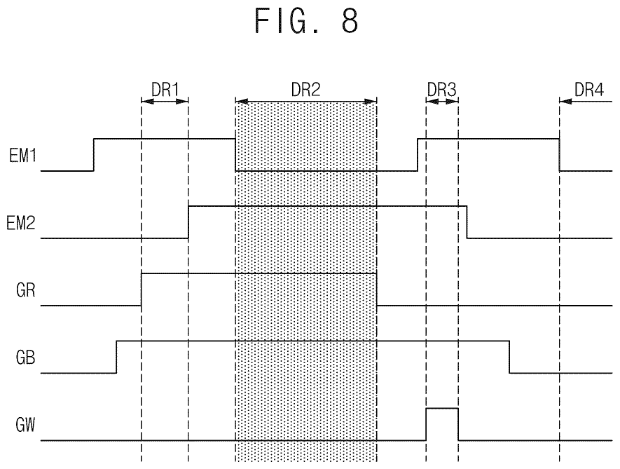

FIG. 7 is an example diagram of an equivalent circuit illustrating an operation of the first type pixel PXA of FIG. 2 in the second period DR2. FIG. 8 is a timing diagram illustrating the input signals applied to the first type pixel PXA of FIG. 2 in the second period DR2.

Referring to FIGS. 1 to 8, in the second period DR2, the first emission signal EM1 may have an active level, the second emission signal EM2 may have an inactive level, the reference gate signal GR may have the active level, the initialization gate signal GB may have the active level and the writing gate signal GW may have the inactive level.

In the second period DR2, the second transistor T2 may be turned off, the third transistor T3 may be turned on, the fourth transistor T4 may be turned on, the fifth transistor T5 may be turned on and the sixth transistor T6 may be turned off. In the second period DR2, the first transistor T1 may be turned on by the reference voltage VREF applied to the first node N1.

In the second period DR2, a turned-on state of the third transistor T3 may be maintained and the reference voltage VREF may be applied to the first node N1.

In the second period DR2, a turned-on state of the fourth transistor T4 may be maintained and the initialization voltage VAINIT may be applied to the anode electrode of the light emitting element EE.

In the second period DR2, the fifth transistor T5 and the first transistor T1 may be turned on so that a voltage of the third node N3 may be a difference between the reference voltage VREF and a threshold voltage of the first transistor T1. A threshold voltage component of the first transistor T1 may be applied to the third node N3 so that the second period DR2 may be referred to as the threshold voltage compensation period.

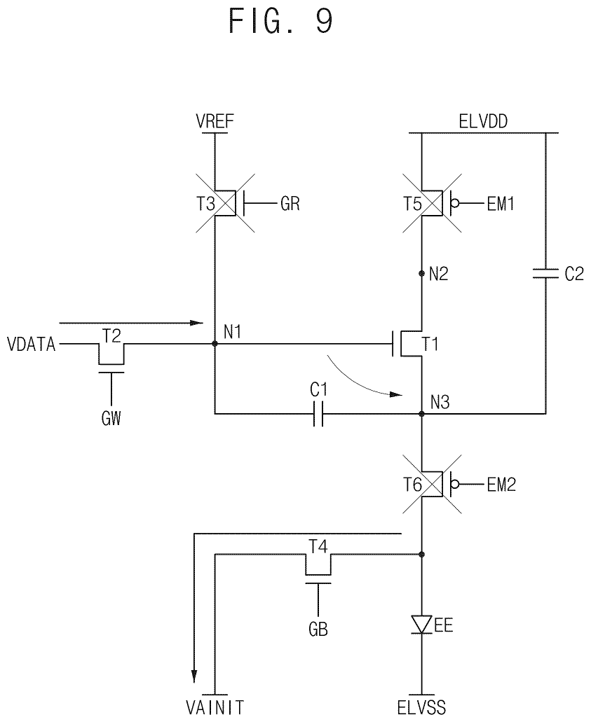

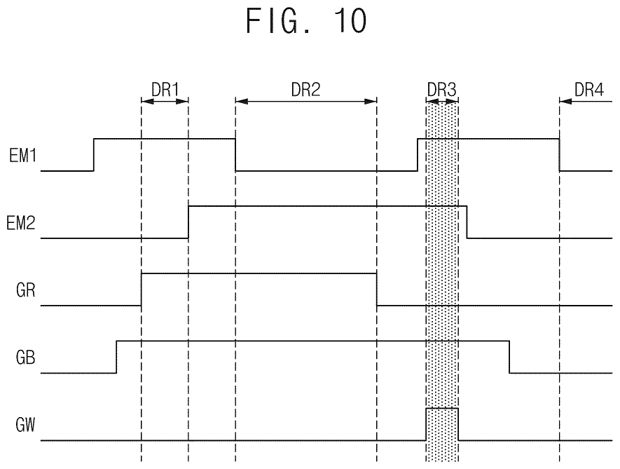

FIG. 9 is an example diagram of an equivalent circuit illustrating an operation of the first type pixel PXA of FIG. 2 in the third period DR3. FIG. 10 is a timing diagram illustrating the input signals applied to the first type pixel PXA of FIG. 2 in the third period DR3.

Referring to FIGS. 1 to 10, in the third period DR3, the first emission signal EM1 may have the inactive level, the second emission signal EM2 may have the inactive level, the reference gate signal GR may have an inactive level, the initialization gate signal GB may have the active level and the writing gate signal GW may have an active level.

In the third period DR3, the second transistor T2 may be turned on, the third transistor T3 may be turned off, the fourth transistor T4 may be turned on, the fifth transistor T5 may be turned off and the sixth transistor T6 may be turned off.

In the third period DR3, the second transistor T2 may be turned on so that the data voltage VDATA may be applied to the first node N1 and the data voltage VDATA may be transmitted to the third node N3 by a coupling of the first capacitor C1.

The data voltage VDATA may be transmitted to the third node N3 according to a ratio (e.g., C1/(C1+C2)) of capacitances of the first capacitor C1 and the second capacitor C2.

In the third period DR3, the turned-on state of the fourth transistor T4 is maintained and the initialization voltage VAINIT may be applied to the anode electrode of the light emitting element EE.

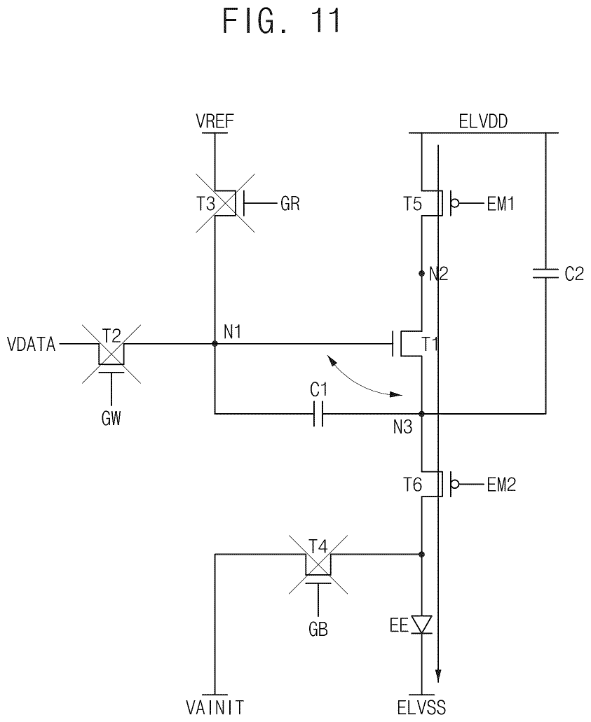

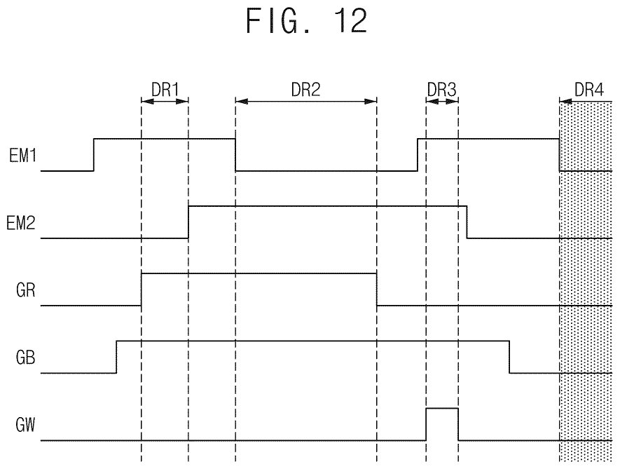

FIG. 11 is an example diagram of an equivalent circuit illustrating an operation of the first type pixel PXA of FIG. 2 in the fourth period DR4. FIG. 12 is a timing diagram illustrating the input signals applied to the first type pixel PXA of FIG. 2 in the fourth period DR4.

Referring to FIGS. 1 to 12, in the fourth period DR4, the first emission signal EM1 may have the active level, the second emission signal EM2 may have the active level, the reference gate signal GR may have the inactive level, the initialization gate signal GB may have an inactive level and the writing gate signal GW may have the inactive level.

In the fourth period DR4, the first transistor T1 may be turned on, the second transistor T2 may be turned off, the third transistor T3 may be turned off, the fourth transistor T4 may be turned off, the fifth transistor T5 may be turned on and the sixth transistor T6 may be turned on.

The driving current of the light emitting element EE may be represented as following Equation 1.

$$I = \frac{1}{2} μ Cox \frac{W}{L} \frac{C 2}{C 1 + C 2} {( VDATA - VREF )}^{2} \qquad [ Equation 1 ]$$

Herein, μ is a mobility, Cox is a capacitance between a gate and a channel, W is a width of the channel and L is a length of the channel of the first transistor T1.

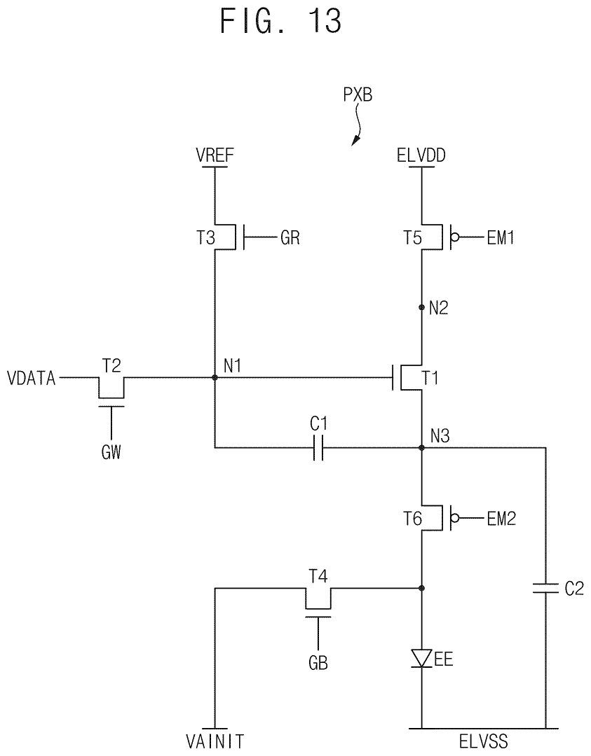

FIG. 13 is an example diagram of an equivalent circuit illustrating the second type pixel PXB of FIG. 2.

A structure of the second type pixel PXB illustrated in FIG. 13 may be substantially the same as the structure of the first type pixel PXA illustrated in FIG. 3 except for the second electrode of the second capacitor C2.

A timing of input signals of the second type pixel PXB illustrated in FIG. 13 and operations of the second type pixel PXB in a first period DR1 to a fourth period DR4 may be substantially the same as the timing of input signals of the first type pixel PXA and operations of the first type pixel PXA in the first period DR1 to the fourth period DR4 explained referring to FIGS. 4 to 12.

Referring to FIGS. 1, 2 and 13, the second type pixel PXB may include the first transistor T1 including a control electrode connected to a first node N1, a first electrode connected to a second node N2 and a second electrode connected to a third node N3, a second transistor T2 including a control electrode receiving the writing gate signal GW, a first electrode receiving the data voltage VDATA and a second electrode connected to the first node N1, a third transistor T3 including a control electrode receiving the reference gate signal GR, a first electrode receiving the reference voltage VREF and a second electrode connected to the first node N1, a fourth transistor T4 including a control electrode receiving the initialization gate signal GB, a first electrode receiving an initialization voltage VAINIT and a second electrode connected to an anode electrode of the light emitting element EE, a fifth transistor T5 including a control electrode receiving the first emission signal EM1, a first electrode receiving the first power voltage ELVDD and a second electrode connected to the second node N2, a sixth transistor T6 including a control electrode receiving the second emission signal EM2, a first electrode connected to the third node N3 and a second electrode connected to the anode electrode of the light emitting element EE, the light emitting element EE including the anode electrode and a cathode electrode receiving the second power voltage ELVSS, a first capacitor C1 including a first electrode connected to the first node N1 and a second electrode connected to the third node N3, and a second capacitor C2 including a first electrode connected to the third node N3 and a second electrode receiving the second power voltage ELVSS.

In the embodiment, the first power voltage ELVDD may be applied to the second electrode of the second capacitor C2 of the first type pixel PXA and the second power voltage ELVSS may be applied to the second electrode of the second capacitor C2 of the second type pixel PXB.

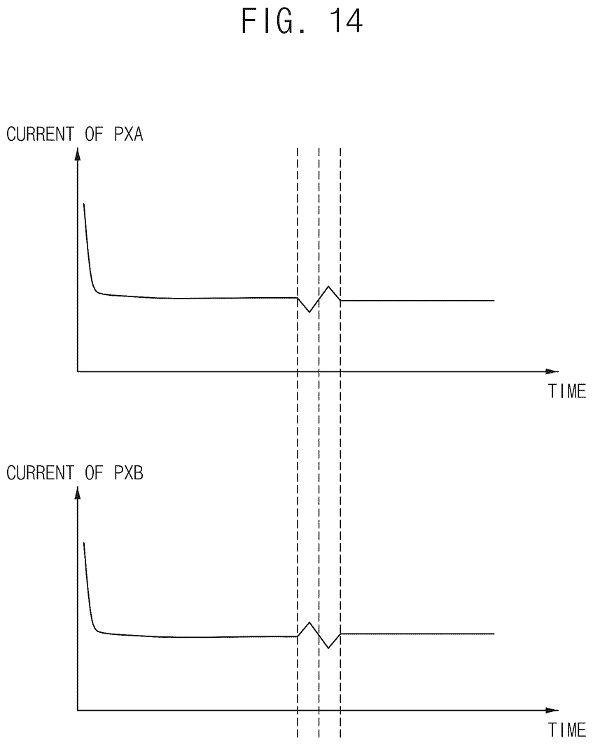

FIG. 14 is a graph illustrating an example of a driving current of the first type pixel PXA of FIG. 2 and an example of a driving current of the second type pixel PXB of FIG. 2.

Referring to FIGS. 1 to 14, the first type pixel PXA and the second type pixel PXB may have different connection relations of the second capacitors. For example, the first power voltage ELVDD may be applied to the second electrode of the second capacitor C2 of the first type pixel PXA and a voltage (e.g., the second power voltage ELVSS of FIG. 13) different from the first power voltage ELVDD may be applied to the second electrode of the second capacitor C2 of the second type pixel PXB.

A level of the first power voltage ELVDD may fluctuate according to time. For example, the level of the first power voltage ELVDD may fluctuate due to external signal noise. For example, for a case in which a writing cycle of the writing gate signal GW and light emitting cycle of the light emitting element EE are different from each other, the level of the first power voltage ELVDD may fluctuate in a cycle in which the writing gate signal GW is not written and the light emitting element EE emits light. Accordingly, the bright portion and the dark portion may be generated in some parts of the display panel 100.

The first type pixel PXA includes the second capacitor C2 connected to the first power voltage ELVDD. For a case in which the level of the first power voltage ELVDD fluctuates, a voltage level of a source electrode (or ‘the third node N3’) of the first transistor T1 may fluctuate.

For example, for a case in which the first power voltage ELVDD increases, a gate-source voltage of the first transistor T1 may decrease in the first type pixel PXA and a driving current of the light emitting element EE may decrease in the first type pixel PXA so that a luminance of the light emitting element EE may decrease in the first type pixel PXA. For a case in which the first power voltage ELVDD decreases, the gate-source voltage of the first transistor T1 may increase in the first type pixel PXA and the driving current of the light emitting element EE may increase in the first type pixel PXA so that the luminance of the light emitting element EE may increase in the first type pixel PXA.

The second type pixel PXB includes the second capacitor C2 connected to the second power voltage ELVSS. For a case in which the level of the second power voltage ELVSS fluctuates, a voltage level of a source electrode (or ‘the third node N3’) of the first transistor T1 may fluctuate. Generally, the first power voltage ELVDD and the second power voltage ELVSS have opposite polarities. Thus, for a case in which the first power voltage ELVDD increases, the second power voltage ELVSS may decrease, and for a case in which the first power voltage ELVDD decreases, the second power voltage ELVSS may increase.

For example, for a case in which the second power voltage ELVSS decreases (or ‘the first power voltage ELVDD increases’), a gate-source voltage of the first transistor T1 may increase in the second type pixel PXB and a driving current of the light emitting element EE may increase in the second type pixel PXB so that a luminance of the light emitting element EE may increase in the second type pixel PXB. For a case in which the second power voltage ELVSS increases (or ‘the first power voltage ELVDD decreases’), the gate-source voltage of the first transistor T1 may decrease in the second type pixel PXB and the driving current of the light emitting element EE may decrease in the second type pixel PXB so that the luminance of the light emitting element EE may decrease in the second type pixel PXB.

For a case in which the display panel 100 includes only the first type pixels PXA, the bright portion and the dark portion may be generated in a unit of a horizontal line and may correspond to multiple horizontal lines. For example, a shape of the bright portion and a shape of the dark portion may have a rectangular shape which covers an entire area of the display panel 100 in a horizontal direction D1 and covers a part of the display panel 100 in a vertical direction D2.

For a case in which the first type pixel PXA and the second type pixel PXB are alternately disposed in the display panel 100 in the first direction (or ‘the horizontal direction’) D1, the bright portion and the dark portion might not be readily perceived in the horizontal direction D1.

For a case in which the first type pixel PXA and the second type pixel PXB are alternately disposed in the display panel 100 in the second direction (or ‘the vertical direction’) D2, the bright portion and the dark portion may be alternated on every horizontal line so that the bright portion and the dark portion might not be readily perceived in the vertical direction D2.

According to the embodiment, for a case in which the first type pixel (or ‘the first pixel’) PXA becomes the bright portion due to a change of the first power voltage ELVDD, the second type pixel (or ‘the second pixel’) PXB having the second capacitor C2 receiving the second power voltage ELVSS may become the dark portion. For a case in which the first type pixel PXA becomes the dark portion due to the change of the first power voltage ELVDD, the second type pixel PXB having the second capacitor C2 receiving the second power voltage ELVSS may become the bright portion.

Thus, a luminance change of the first type pixel PXA and a luminance change of the second type pixel PXB may offset each other so that the bright portion and the dark portion may not be perceived by a user, and accordingly, the display quality of the display panel 100 may be enhanced.

Thus in the embodiments of the disclosure, two different pixel circuit designs for two different pixels PXA and PXB are incorporated in the display that are arranged in an alternating manner in one or both of the first direction DR1 and the second direction DR2. When a voltage fluctuation occurs due to noise in one of the power voltage supplies, such a design may result in bright and dark spots alternating on a pixel-by-pixel basis so that when bright and dark spots form due to voltage fluctuations of the power supply, the reduction in the perceived display quality is minimized. In contrast, when a same pixel is used throughout a line, column, or throughout the display area, the entire line (or portions of an entire line) or an entire display area sub-area of the display would appear as a bright spot or a dark spot, which would otherwise be more noticeable.

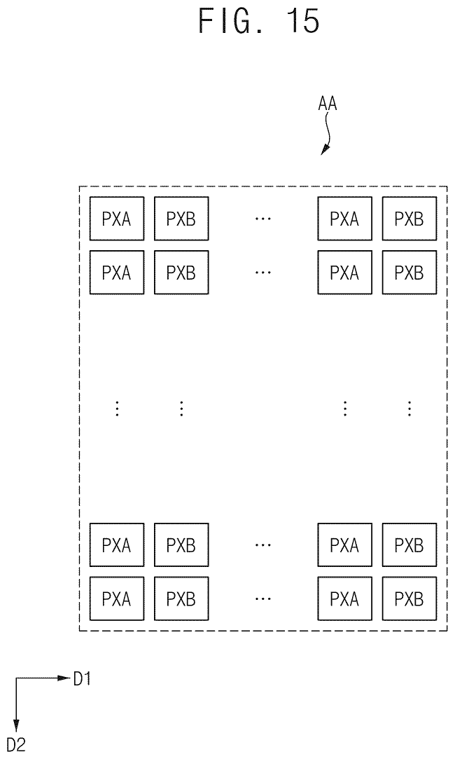

FIG. 15 is a diagram illustrating an arrangement of a first type pixel PXA and a second type pixel PXB of a display panel 100 of a display apparatus according to an embodiment of the disclosure.

The display apparatus according to the embodiment of FIG. 15 is substantially the same as the display apparatus of the previous embodiment explained referring to FIGS. 1 to 14 except for an arrangement of the first type pixel PXA and the second type pixel PXB. Thus, the same reference numerals will be used to refer to the same or like parts as those described in the previous embodiment of FIGS. 1 to 14 and any repetitive explanation concerning the above elements will be omitted.

Referring to FIGS. 1 and 3 to 15, the first type pixel PXA and the second type pixel PXB may be disposed adjacent to each other in the display area AA.

In the embodiment, the first type pixels PXA and the second type pixels PXB may be alternately disposed in the first direction D1.

In the embodiment, the first type pixels PXA and the second type pixels PXB may be alternately disposed in the first direction D1 so that a bright portion and a dark portion of the display panel 100 may not be perceived by a user.

For a case in which the display panel 100 includes only the first type pixels PXA, the bright portion and the dark portion may be generated in a unit of a horizontal line and may correspond to multiple horizontal lines. For example, a shape of the bright portion and a shape of the dark portion may have a rectangular shape which covers an entire sub-area of the display panel 100 in a horizontal direction D1 and covers a part of the display panel 100 in a vertical direction D2.

For a case in which the first type pixel PXA and the second type pixel PXB are alternately disposed in the display panel 100 in the first direction (or ‘the horizontal direction’) D1, the bright portion and the dark portion might not be well perceived in the horizontal direction D1.

According to the embodiment, for a case in which the first type pixel (or ‘the first pixel’) PXA becomes the bright portion due to a change of the first power voltage ELVDD, the second type pixel (or ‘the second pixel’) PXB having the second capacitor C2 receiving the second power voltage ELVSS may become the dark portion. For a case in which the first type pixel PXA becomes the dark portion due to the change of the first power voltage ELVDD, the second type pixel PXB having the second capacitor C2 receiving the second power voltage ELVSS may become the bright portion.

Thus, a luminance change of the first type pixel PXA and a luminance change of the second type pixel PXB may offset each other so that the bright portion and the dark portion may not be perceived by a user, and accordingly, the display quality of the display panel 100 may be enhanced.

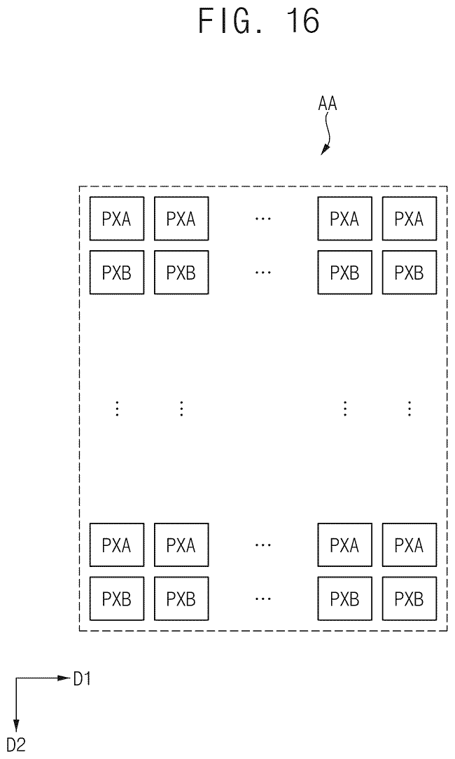

FIG. 16 is an example diagram illustrating an arrangement of a first type pixel PXA and a second type pixel PXB of a display panel 100 of a display apparatus according to an embodiment of the disclosure.

The display apparatus according to the embodiment is substantially the same as the display apparatus of the previous embodiment explained referring to FIGS. 1 to 14 except for an arrangement of the first type pixel PXA and the second type pixel PXB. Thus, the same reference numerals will be used to refer to the same or like parts as those described in the previous embodiment of FIGS. 1 to 14 and any repetitive explanation concerning the above elements will be omitted.

Referring to FIGS. 1, 3 to 14 and 16, the first type pixel PXA and the second type pixel PXB may be disposed adjacent to each other in the display area AA.

In the embodiment, the first type pixels PXA and the second type pixels PXB may be alternately disposed in the second direction D2.

In the embodiment, the first type pixels PXA and the second type pixels PXB may be alternately disposed in the first direction D2 so that a bright portion and a dark portion of the display panel 100 may not be perceived by a user.

For a case in which the display panel 100 includes only the first type pixels PXA, the bright portion and the dark portion may be generated in a unit of a horizontal line and may correspond to multiple horizontal lines. For example, a shape of the bright portion and a shape of the dark portion may have a rectangular shape which covers an entire area of the display panel 100 in a horizontal direction D1 and covers a part of the display panel 100 in a vertical direction D2.

For a case in which the first type pixel PXA and the second type pixel PXB are alternately disposed in the display panel 100 in the second direction (or ‘the vertical direction’) D2, the bright portion and the dark portion may be alternated on every horizontal line so that the bright portion and the dark portion might not be well perceived in the vertical direction D2.

According to the embodiment, for a case in which the first type pixel (or ‘the first pixel’) PXA becomes the bright portion due to a change of the first power voltage ELVDD, the second type pixel (or ‘the second pixel’) PXB having the second capacitor C2 receiving the second power voltage ELVSS may become the dark portion. For a case in which the first type pixel PXA becomes the dark portion due to the change of the first power voltage ELVDD, the second type pixel PXB having the second capacitor C2 receiving the second power voltage ELVSS may become the bright portion.

Thus, a luminance change of the first type pixel PXA and a luminance change of the second type pixel PXB may offset each other so that the bright portion and the dark portion may not be perceived by a user, and accordingly, the display quality of the display panel 100 may be enhanced.

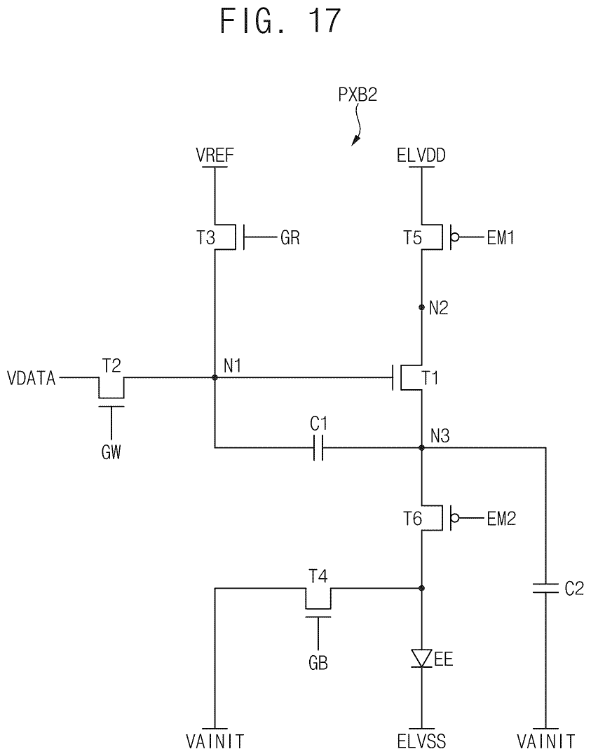

FIG. 17 is an example diagram of an equivalent circuit illustrating a second type pixel PXB2 of a display panel 100 of a display apparatus according to an embodiment of the disclosure.

The display apparatus according to the embodiment is substantially the same as the display apparatus of the previous embodiment explained referring to FIGS. 1 to 14 except for a voltage applied to a second electrode of a second capacitor of the second type pixel PXB2. Thus, the same reference numerals will be used to refer to the same or like parts as those described in the previous embodiment of FIGS. 1 to 14 and any repetitive explanation concerning the above elements will be omitted and to the extent that an element is not described in detail with respect to this figure, it may be understood that the element is at least similar to a corresponding element that has been described elsewhere within the present disclosure.

Referring to FIGS. 1 to 12 and 17, the first type pixel PXA and the second type pixel PXB2 may be disposed adjacent to each other in the display area AA.

In the embodiment, like FIG. 2, the first type pixels PXA and the second type pixels PXB2 may be alternately disposed in the first direction D1 and the second direction D2.

As another example, like FIG. 15, the first type pixels PXA and the second type pixels PXB2 may be alternately disposed in the first direction D1.

As another example, like FIG. 16, the first type pixels PXA and the second type pixels PXB2 may be alternately disposed in the second direction D2.

The first type pixel PXA may include the first transistor T1 including a control electrode connected to a first node N1, a first electrode connected to a second node N2 and a second electrode connected to a third node N3, a second transistor T2 including a control electrode receiving the writing gate signal GW, a first electrode receiving the data voltage VDATA and a second electrode connected to the first node N1, a third transistor T3 including a control electrode receiving the reference gate signal GR, a first electrode receiving the reference voltage VREF and a second electrode connected to the first node N1, a fourth transistor T4 including a control electrode receiving the initialization gate signal GB, a first electrode receiving an initialization voltage VAINIT and a second electrode connected to an anode electrode of the light emitting element EE, a fifth transistor T5 including a control electrode receiving the first emission signal EM1, a first electrode receiving the first power voltage ELVDD and a second electrode connected to the second node N2, a sixth transistor T6 including a control electrode receiving the second emission signal EM2, a first electrode connected to the third node N3 and a second electrode connected to the anode electrode of the light emitting element EE, the light emitting element EE including the anode electrode and a cathode electrode receiving the second power voltage ELVSS, a first capacitor C1 including a first electrode connected to the first node N1 and a second electrode connected to the third node N3 and a second capacitor C2 including a first electrode connected to the third node N3 and a second electrode receiving the first power voltage ELVDD.

The second type pixel PXB2 may include the first transistor T1 including a control electrode connected to a first node N1, a first electrode connected to a second node N2 and a second electrode connected to a third node N3, a second transistor T2 including a control electrode receiving the writing gate signal GW, a first electrode receiving the data voltage VDATA and a second electrode connected to the first node N1, a third transistor T3 including a control electrode receiving the reference gate signal GR, a first electrode receiving the reference voltage VREF and a second electrode connected to the first node N1, a fourth transistor T4 including a control electrode receiving the initialization gate signal GB, a first electrode receiving an initialization voltage VAINIT and a second electrode connected to an anode electrode of the light emitting element EE, a fifth transistor T5 including a control electrode receiving the first emission signal EM1, a first electrode receiving the first power voltage ELVDD and a second electrode connected to the second node N2, a sixth transistor T6 including a control electrode receiving the second emission signal EM2, a first electrode connected to the third node N3 and a second electrode connected to the anode electrode of the light emitting element EE, the light emitting element EE including the anode electrode and a cathode electrode receiving the second power voltage ELVSS, a first capacitor C1 including a first electrode connected to the first node N1 and a second electrode connected to the third node N3 and a second capacitor C2 including a first electrode connected to the third node N3 and a second electrode receiving the initialization voltage VAINIT.

In the embodiment, the first power voltage ELVDD may be applied to the second electrode of the second capacitor C2 of the first type pixel PXA and the initialization voltage VAINIT may be applied to the second electrode of the second capacitor C2 of the second type pixel PXB2.

A level of the first power voltage ELVDD may fluctuate according to time. A level of the initialization voltage VAINIT may fluctuate according to time.

In the embodiment, a level change of the first power voltage ELVDD may have little correlation with a level change of the initialization voltage VAINIT.

According to the embodiment, for a case in which the first type pixel (or ‘the first pixel’) PXA becomes the bright portion due to a change of the first power voltage ELVDD, the second type pixel (or ‘the second pixel’) PXB2 having the second capacitor C2 receiving the initialization voltage VAINIT may become the dark portion compared to the first type pixel (or ‘the first pixel’) PXA since the level of the initialization voltage VAINIT has a little correlation with the level of the first power voltage ELVDD. For a case in which the first type pixel PXA becomes the dark portion due to the change of the first power voltage ELVDD, the second type pixel (or ‘the second pixel’) PXB2 having the second capacitor C2 receiving the initialization voltage VAINIT may become the bright portion compared to the first type pixel (or ‘the first pixel’) PXA.

Thus, a degree of visibility of the luminance change of the first type pixel PXA may be reduced so that the bright portion and the dark portion may not be perceived by a user, and accordingly, the display quality of the display panel 100 may be enhanced.

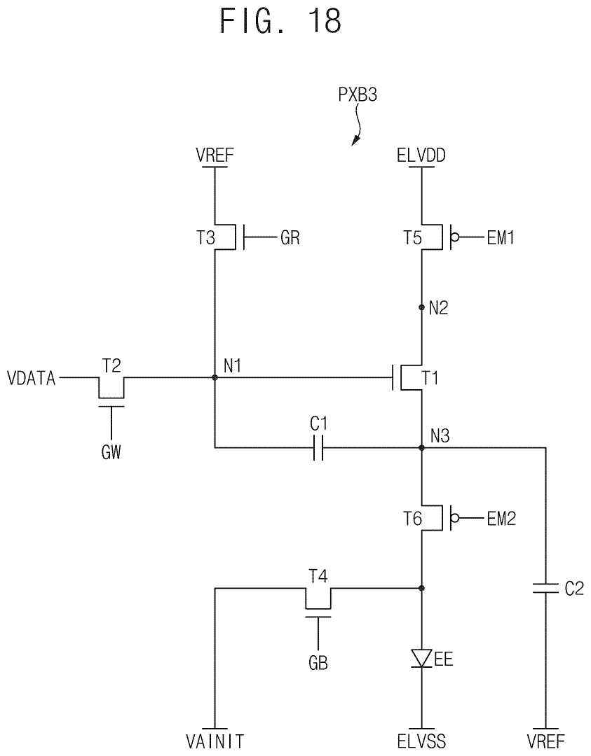

FIG. 18 is an example diagram of an equivalent circuit illustrating a second type pixel PXB3 of a display panel 100 of a display apparatus according to an embodiment of the disclosure.

The display apparatus according to the embodiment is substantially the same as the display apparatus of the previous embodiment explained referring to FIGS. 1 to 14 except for a voltage applied to a second electrode of a second capacitor of the second type pixel PXB3. Thus, the same reference numerals will be used to refer to the same or like parts as those described in the previous embodiment of FIGS. 1 to 14 and any repetitive explanation concerning the above elements will be omitted.

Referring to FIGS. 1 to 12 and 18, the first type pixel PXA and the second type pixel PXB3 may be disposed adjacent to each other in the display area AA.

In the embodiment, like FIG. 2, the first type pixels PXA and the second type pixels PXB3 may be alternately disposed in the first direction D1 and the second direction D2.

As another example, like FIG. 15, the first type pixels PXA and the second type pixels PXB3 may be alternately disposed in the first direction D1.

As another example, like FIG. 16, the first type pixels PXA and the second type pixels PXB3 may be alternately disposed in the second direction D2.

The first type pixel PXA may include the first transistor T1 including a control electrode connected to a first node N1, a first electrode connected to a second node N2 and a second electrode connected to a third node N3, a second transistor T2 including a control electrode receiving the writing gate signal GW, a first electrode receiving the data voltage VDATA and a second electrode connected to the first node N1, a third transistor T3 including a control electrode receiving the reference gate signal GR, a first electrode receiving the reference voltage VREF and a second electrode connected to the first node N1, a fourth transistor T4 including a control electrode receiving the initialization gate signal GB, a first electrode receiving an initialization voltage VAINIT and a second electrode connected to an anode electrode of the light emitting element EE, a fifth transistor T5 including a control electrode receiving the first emission signal EM1, a first electrode receiving the first power voltage ELVDD and a second electrode connected to the second node N2, a sixth transistor T6 including a control electrode receiving the second emission signal EM2, a first electrode connected to the third node N3 and a second electrode connected to the anode electrode of the light emitting element EE, the light emitting element EE including the anode electrode and a cathode electrode receiving the second power voltage ELVSS, a first capacitor C1 including a first electrode connected to the first node N1 and a second electrode connected to the third node N3 and a second capacitor C2 including a first electrode connected to the third node N3 and a second electrode receiving the first power voltage ELVDD.

The second type pixel PXB3 may include the first transistor T1 including a control electrode connected to a first node N1, a first electrode connected to a second node N2 and a second electrode connected to a third node N3, a second transistor T2 including a control electrode receiving the writing gate signal GW, a first electrode receiving the data voltage VDATA and a second electrode connected to the first node N1, a third transistor T3 including a control electrode receiving the reference gate signal GR, a first electrode receiving the reference voltage VREF and a second electrode connected to the first node N1, a fourth transistor T4 including a control electrode receiving the initialization gate signal GB, a first electrode receiving an initialization voltage VAINIT and a second electrode connected to an anode electrode of the light emitting element EE, a fifth transistor T5 including a control electrode receiving the first emission signal EM1, a first electrode receiving the first power voltage ELVDD and a second electrode connected to the second node N2, a sixth transistor T6 including a control electrode receiving the second emission signal EM2, a first electrode connected to the third node N3 and a second electrode connected to the anode electrode of the light emitting element EE, the light emitting element EE including the anode electrode and a cathode electrode receiving the second power voltage ELVSS, a first capacitor C1 including a first electrode connected to the first node N1 and a second electrode connected to the third node N3 and a second capacitor C2 including a first electrode connected to the third node N3 and a second electrode receiving the reference voltage VREF.

In the embodiment, the first power voltage ELVDD may be applied to the second electrode of the second capacitor C2 of the first type pixel PXA and the reference voltage VREF may be applied to the second electrode of the second capacitor C2 of the second type pixel PXB3.

A level of the first power voltage ELVDD may fluctuate according to time. A level of the reference voltage VREF may fluctuate according to time.

In the embodiment, a level change of the first power voltage ELVDD may have little correlation with a level change of the reference voltage VREF.

According to the embodiment, for a case in which the first type pixel (or ‘the first pixel’) PXA becomes the bright portion due to a change of the first power voltage ELVDD, the second type pixel (or ‘the second pixel’) PXB3 having the second capacitor C2 receiving the reference voltage VREF may become the dark portion compared to the first type pixel (or ‘the first pixel’) PXA since the level of the reference voltage VREF has a little correlation with the level of the first power voltage ELVDD. For a case in which the first type pixel PXA becomes the dark portion due to the change of the first power voltage ELVDD, the second type pixel (or ‘the second pixel’) PXB3 having the second capacitor C2 receiving the reference voltage VREF may become the bright portion compared to the first type pixel (or ‘the first pixel’) PXA.

Thus, the visibility of the first type pixel PXA may be reduced so that the bright portion and the dark portion may not be perceived by a user, and accordingly, the display quality of the display panel 100 may be enhanced.

FIG. 19 is an example diagram of an equivalent circuit illustrating a first type pixel PXA4 of a display panel 100 of a display apparatus according to an embodiment of the disclosure.

The display apparatus according to the embodiment is substantially the same as the display apparatus of the previous embodiment explained referring to FIGS. 1 to 14 except that a first transistor of the first type pixel PXA4 further includes a second control electrode. Thus, the same reference numerals will be used to refer to the same or like parts as those described in the previous embodiment of FIGS. 1 to 14 and any repetitive explanation concerning the above elements will be omitted.

Referring to FIGS. 1, 2, 4 to 14 and 19, the first type pixel PXA4 may include the first transistor T1 including a control electrode connected to a first node N1, a first electrode connected to a second node N2 and a second electrode connected to a third node N3, a second transistor T2 including a control electrode receiving the writing gate signal GW, a first electrode receiving the data voltage VDATA and a second electrode connected to the first node N1, a third transistor T3 including a control electrode receiving the reference gate signal GR, a first electrode receiving the reference voltage VREF and a second electrode connected to the first node N1, a fourth transistor T4 including a control electrode receiving the initialization gate signal GB, a first electrode receiving an initialization voltage VAINIT and a second electrode connected to an anode electrode of the light emitting element EE, a fifth transistor T5 including a control electrode receiving the first emission signal EM1, a first electrode receiving the first power voltage ELVDD and a second electrode connected to the second node N2, a sixth transistor T6 including a control electrode receiving the second emission signal EM2, a first electrode connected to the third node N3 and a second electrode connected to the anode electrode of the light emitting element EE, the light emitting element EE including the anode electrode and a cathode electrode receiving the second power voltage ELVSS, a first capacitor C1 including a first electrode connected to the first node N1 and a second electrode connected to the third node N3 and a second capacitor C2 including a first electrode connected to the third node N3 and a second electrode receiving the first power voltage ELVDD.

In the embodiment, the first transistor T1 of the first type pixel PXA4 may further include a second control electrode connected to the third node N3. The first transistor T1 further includes the second control electrode so that a turn-on characteristic of the first transistor T1 may be enhanced.

According to the embodiment, for a case in which the first type pixel (or ‘the first pixel’) PXA4 becomes the bright portion due to a change of the first power voltage ELVDD, the second type pixel (or ‘the second pixel’) PXB having the second capacitor C2 receiving the second power voltage ELVSS may become the dark portion. For a case in which the first type pixel PXA4 becomes the dark portion due to the change of the first power voltage ELVDD, the second type pixel PXB having the second capacitor C2 receiving the second power voltage ELVSS may become the bright portion.

Thus, a luminance change of the first type pixel PXA4 and a luminance change of the second type pixel PXB may offset each other so that the bright portion and the dark portion may not be perceived by a user, and accordingly, the display quality of the display panel 100 may be enhanced.

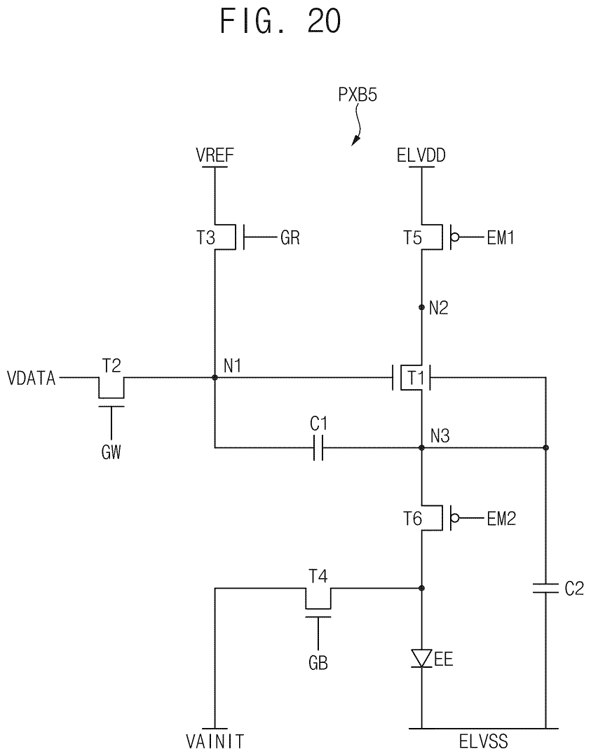

FIG. 20 is an example diagram of an equivalent circuit illustrating a second type pixel PXB5 of a display panel 100 of a display apparatus according to an embodiment of the disclosure.

The display apparatus according to the embodiment is substantially the same as the display apparatus of the previous embodiment explained referring to FIGS. 1 to 14 except that a first transistor of the second type pixel PXB5 further includes a second control electrode. Thus, the same reference numerals will be used to refer to the same or like parts as those described in the previous embodiment of FIGS. 1 to 14 and any repetitive explanation concerning the above elements will be omitted.

Referring to FIGS. 1 to 12, 14 and 20, the second type pixel PXB5 may include the first transistor T1 including a control electrode connected to a first node N1, a first electrode connected to a second node N2 and a second electrode connected to a third node N3, a second transistor T2 including a control electrode receiving the writing gate signal GW, a first electrode receiving the data voltage VDATA and a second electrode connected to the first node N1, a third transistor T3 including a control electrode receiving the reference gate signal GR, a first electrode receiving the reference voltage VREF and a second electrode connected to the first node N1, a fourth transistor T4 including a control electrode receiving the initialization gate signal GB, a first electrode receiving an initialization voltage VAINIT and a second electrode connected to an anode electrode of the light emitting element EE, a fifth transistor T5 including a control electrode receiving the first emission signal EM1, a first electrode receiving the first power voltage ELVDD and a second electrode connected to the second node N2, a sixth transistor T6 including a control electrode receiving the second emission signal EM2, a first electrode connected to the third node N3 and a second electrode connected to the anode electrode of the light emitting element EE, the light emitting element EE including the anode electrode and a cathode electrode receiving the second power voltage ELVSS, a first capacitor C1 including a first electrode connected to the first node N1 and a second electrode connected to the third node N3 and a second capacitor C2 including a first electrode connected to the third node N3 and a second electrode receiving the second power voltage ELVSS.

In the embodiment, the first transistor T1 of the second type pixel PXB5 may further include a second control electrode connected to the third node N3. The first transistor T1 further includes the second control electrode so that a turn-on characteristic of the first transistor T1 may be enhanced.

According to the embodiment, for a case in which the first type pixel (or ‘the first pixel’) PXA becomes the bright portion due to a change of the first power voltage ELVDD, the second type pixel (or ‘the second pixel’) PXB5 having the second capacitor C2 receiving the second power voltage ELVSS may become the dark portion. For a case in which the first type pixel PXA becomes the dark portion due to the change of the first power voltage ELVDD, the second type pixel PXB5 having the second capacitor C2 receiving the second power voltage ELVSS may become the bright portion.

Thus, a luminance change of the first type pixel PXA and a luminance change of the second type pixel PXB5 may offset each other so that the bright portion and the dark portion may not be perceived by a user, and accordingly, the display quality of the display panel 100 may be enhanced.

Thus, by including two different designs for pixel circuits where one end of capacitor C2 is connected to a different power source in the second pixel PXB than in the first pixel PXA, and by arranging the first and second pixels in an alternating manner, the user is less apt to see the anomaly of bright or dark spots being displayed when a voltage fluctuation of a power source occurs.

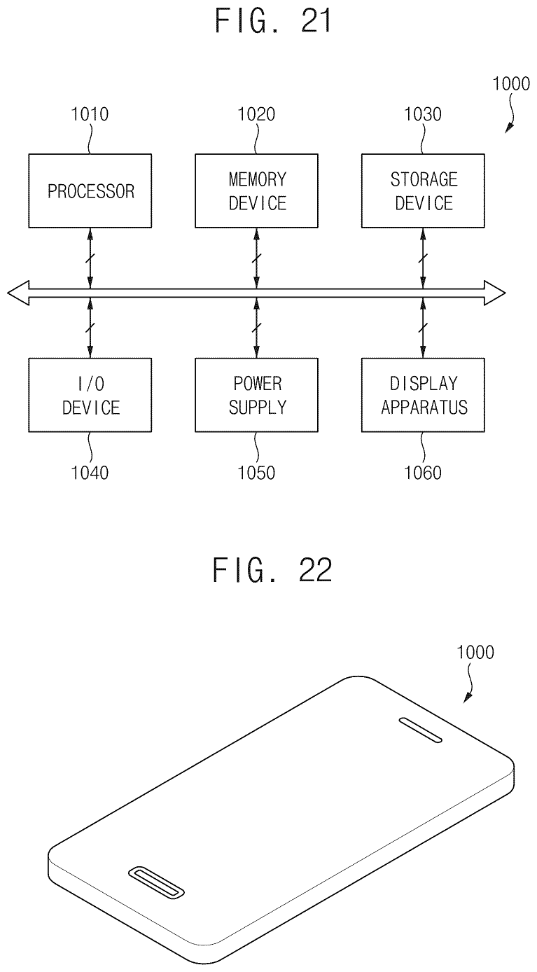

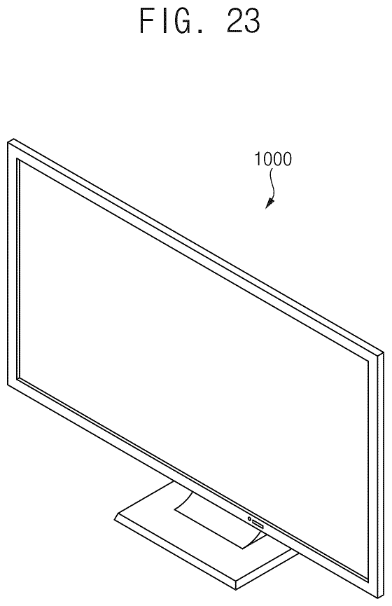

FIG. 21 is an example block diagram illustrating an electronic apparatus 1000 according to an embodiment of the disclosure. FIG. 22 is a diagram illustrating an example in which the electronic apparatus 1000 of FIG. 21 is implemented as a smartphone. FIG. 23 is a diagram illustrating an example in which the electronic apparatus 1000 of FIG. 21 is implemented as a monitor.

Referring to FIGS. 21 to 23, the electronic apparatus 1000 may include a processor 1010, a memory device 1020, a storage device 1030, an input/output (I/O) device 1040, a power supply 1050, and a display apparatus 1060. Here, the display apparatus 1060 may be the display apparatus of FIG. 1. The electronic apparatus 1000 may further include multiple ports for communicating with a video card, a sound card, a memory card, a universal serial bus (USB) device, other electronic apparatuses, etc.

In an embodiment, as illustrated in FIG. 22, the electronic apparatus 1000 may be implemented as a smartphone. In an embodiment, as illustrated in FIG. 23, the electronic apparatus 1000 may be implemented as a monitor. However, the electronic apparatus 1000 is not necessarily limited thereto. For example, the electronic apparatus 1000 may be implemented as a television, a cellular phone, a video phone, a smart pad, a smart watch, a tablet, a car navigation system, a laptop, a head mounted display (HMD) device, and the like.

The processor 1010 may perform various computing functions or various tasks. The processor 1010 may be a micro-processor, a central processing unit (CPU), an application processor (AP), and the like. The processor 1010 may be coupled to other components via an address bus, a control bus, a data bus, etc. Further, the processor 1010 may be coupled to an extended bus such as a peripheral component interconnection (PCI) bus.

The processor 1010 may output the input image data IMG and the input control signal CONT to the driving controller 200 of FIG. 1. The processor 1010 may also be referred to a host.

The memory device 1020 may store data for operations of the electronic apparatus 1000. For example, the memory device 1020 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, and the like and/or at least one volatile memory device such as a dynamic random access memory (DRAM) device, a static random access memory (SRAM) device, a mobile DRAM device, and the like.

The storage device 1030 may include a solid state drive (SSD) device, a hard disk drive (HDD) device, a CD-ROM device, and the like. The I/O device 1040 may include an input device such as a keyboard, a keypad, a mouse device, a touch-pad, a touch-screen, and the like and an output device such as a printer, a speaker, and the like. In some embodiments, the display apparatus 1060 may be included in the I/O device 1040. The power supply 1050 may provide power for operations of the electronic apparatus 1000. The display apparatus 1060 may be coupled to other components via the buses or other communication links.

According to the embodiments of the display panel, the display apparatus including the display panel and the electronic apparatus including the display apparatus, the display quality of the display panel may be enhanced.

The foregoing is illustrative of the disclosure and is not necessarily to be construed as limiting thereof. Although a few embodiments of the disclosure have been described, those skilled in the art will readily appreciate that many modifications are possible in the embodiments without materially departing from the novel teachings and advantages of the disclosure. Accordingly, all such modifications are intended to be included within the scope of the disclosure as defined in the claims. In the claims, means-plus-function clauses are intended to cover the structures described herein as performing the recited function and not only structural equivalents but also equivalent structures. Therefore, it is to be understood that the foregoing is illustrative of the disclosure and is not necessarily to be construed as limited to the specific embodiments disclosed, and that modifications to the disclosed embodiments, as well as other embodiments, are intended to be included within the scope of the appended claims. The disclosure is defined by the following claims, with equivalents of the claims to be included therein.

What is claimed is:

1. A display panel comprising:
a first pixel and a second pixel disposed adjacent to the first pixel, wherein
the first pixel comprises:
a light emitting element;
a first transistor including a control electrode connected to a first node, a first electrode connected to a second node and a second electrode connected to a third node, the first transistor being configured to transmit a driving current to the light emitting element;
a second transistor configured to apply a data voltage of the first pixel to the first node;
a first capacitor including a first electrode connected to the first node and a second electrode connected to the third node; and
a second capacitor including a first electrode connected to the third node and a second electrode configured to receive a first power voltage, and
wherein the second pixel comprises:
a light emitting element;
a first transistor including a control electrode connected to a first node, a first electrode connected to a second node and a second electrode connected to a third node, the first transistor being configured to transmit a driving current to the light emitting element;
a second transistor configured to apply a data voltage of the second pixel to the first node;
a first capacitor including a first electrode connected to the first node and a second electrode connected to the third node; and
a second capacitor including a first electrode connected to the third node and a second electrode configured to receive a voltage different from the first power voltage, and
the first power voltage is a driving voltage of each of the first pixel and the second pixel for generating the driving current.

2. The display panel of claim 1, wherein
a second power voltage is applied to a cathode electrode of the light emitting element of the first pixel and a cathode electrode of the light emitting element of the second pixel,
the second power voltage is applied to the second electrode of the second capacitor of the second pixel, and
the second power is a lower driving voltage of each of the first pixel and the second pixel.

3. The display panel of claim 1, wherein
the first pixel further comprises a third transistor configured to apply a reference voltage to the first node of the first pixel, and
the second pixel further comprises a third transistor configured to apply the reference voltage to the first node of the second pixel.

4. The display panel of claim 3, wherein the reference voltage is applied to the second electrode of the second capacitor of the second pixel.

5. The display panel of claim 1, wherein
the first pixel further comprises a fourth transistor configured to apply an initialization voltage to the light emitting element of the first pixel, and
the second pixel further comprises a fourth transistor configured to apply the initialization voltage to the light emitting element of the second pixel.

6. The display panel of claim 5, wherein the initialization voltage is applied to the second electrode of the second capacitor of the second pixel.

7. The display panel of claim 1, wherein the first pixel further comprises:
a fifth transistor including a first electrode configured to receive the first power voltage and a second electrode connected to the second node of the first pixel; and
a sixth transistor including a first electrode connected to the third node of the first pixel and a second electrode connected to an anode electrode of the light emitting element of the first pixel, and
wherein the second pixel further comprises:
a fifth transistor including a first electrode configured to receive the first power voltage and a second electrode connected to the second node of the second pixel; and
a sixth transistor including a first electrode connected to the third node of the second pixel and a second electrode connected to an anode electrode of the light emitting element of the second pixel.

8. The display panel of claim 1, wherein the first transistor of the first pixel further includes a second control electrode connected to the third node of the first pixel.

9. The display panel of claim 1, wherein the first transistor of the second pixel further includes a second control electrode connected to the third node of the second pixel.

10. The display panel of claim 1, further comprising:
a gate line extending in a first direction;
a data line extending in a second direction intersecting the first direction; and,
a plurality of first pixels and a plurality of second pixels alternately disposed in the first direction and the second direction.

11. The display panel of claim 1, further comprising:
a gate line extending in a first direction;
a data line extending in a second direction intersecting the first direction; and
a plurality of first pixels and a plurality of second pixels alternately disposed in the first direction.

12. The display panel of claim 1, further comprising:
a gate line extending in a first direction;
a data line extending in a second direction intersecting the first direction; and
a plurality of first pixels and a plurality of second pixels alternately disposed in the second direction.

13. The display panel of claim 1, wherein
a writing gate signal is applied to a control electrode of the second transistor of the first pixel, and
the first pixel further comprises:
a third transistor including a control electrode configured to receive a reference gate signal, a first electrode configured to receive a reference voltage and a second electrode connected to the first node of the first pixel;
a fourth transistor including a control electrode configured to receive an initialization gate signal, a first electrode configured to receive an initialization voltage and a second electrode connected to an anode electrode of the light emitting element of the first pixel;
a fifth transistor including a control electrode configured to receive a first emission signal, a first electrode configured to receive the first power voltage and a second electrode connected to the second node of the first pixel; and
a sixth transistor including a control electrode configured to receive a second emission signal, a first electrode connected to the third node of the first pixel and a second electrode connected to the anode electrode of the light emitting element of the first pixel.

14. The display panel of claim 13, wherein
the writing gate signal is applied to a control electrode of the second transistor of the second pixel, and
the second pixel further comprises:
a third transistor including a control electrode configured to receive the reference gate signal, a first electrode configured to receive the reference voltage and a second electrode connected to the first node of the second pixel;
a fourth transistor including a control electrode configured to receive the initialization gate signal, a first electrode configured to receive the initialization voltage and a second electrode connected to an anode electrode of the light emitting element of the second pixel;
a fifth transistor including a control electrode configured to receive the first emission signal, a first electrode configured to receive the first power voltage and a second electrode connected to the second node of the second pixel; and
a sixth transistor including a control electrode configured to receive the second emission signal, a first electrode connected to the third node of the second pixel and a second electrode connected to the anode electrode of the light emitting element of the second pixel.

15. The display panel of claim 13, wherein
the first emission signal has an inactive level in a first period,
the second emission signal has an active level in the first period,
the reference gate signal has an active level in the first period,
the initialization gate signal has an active level in the first period, and
the writing gate signal has an inactive level in the first period.

16. The display panel of claim 13, wherein
the first emission signal has an active level in a second period,
the second emission signal has an inactive level in the second period,
the reference gate signal has an active level in the second period,
the initialization gate signal has an active level in the second period, and
the writing gate signal has an inactive level in the second period.

17. The display panel of claim 13, wherein
the first emission signal has an inactive level in a third period,
the second emission signal has an inactive level in the third period,
the reference gate signal has an inactive level in the third period,
the initialization gate signal has an active level in the third period, and
the writing gate signal has an active level in the third period.

18. The display panel of claim 13, wherein
the first emission signal has an active level in a fourth period,
the second emission signal has an active level in the fourth period,
the reference gate signal has an inactive level in the fourth period,
the initialization gate signal has an inactive level in the fourth period, and
the writing gate signal has an inactive level in the fourth period.

19. A display apparatus comprising:
a display panel comprising a first pixel and a second pixel disposed adjacent to the first pixel;
a gate driver configured to output a gate signal to the first pixel and the second pixel; and
a data driver configured to output a data voltage to the first pixel and the second pixel, wherein
the first pixel comprises:
a light emitting element;
a first transistor including a control electrode connected to a first node, a first electrode connected to a second node and a second electrode connected to a third node, the first transistor being configured to transmit a driving current to the light emitting element;
a second transistor configured to apply a data voltage of the first pixel to the first node;
a first capacitor including a first electrode connected to the first node and a second electrode connected to the third node; and
a second capacitor including a first electrode connected to the third node and a second electrode configured to receive a first power voltage, and
the second pixel comprises:
a light emitting element;
a first transistor including a control electrode connected to a first node, a first electrode connected to a second node and a second electrode connected to a third node, the first transistor being configured to transmit a driving current to the light emitting element;
a second transistor configured to apply a data voltage of the second pixel to the first node;
a first capacitor including a first electrode connected to the first node and a second electrode connected to the third node; and
a second capacitor including a first electrode connected to the third node and a second electrode configured to receive a voltage different from the first power voltage, and
the first power voltage is a driving voltage of each of the first pixel and the second pixel for generating the driving current.

20. An electronic device comprising:
a display panel comprising a first pixel and a second pixel disposed adjacent to the first pixel;
a gate driver configured to output a gate signal to the first pixel and the second pixel;
a data driver configured to output a data voltage to the first pixel and the second pixel;
a driving controller configured to control the gate driver and the data driver; and
a processor configured to output input image data and an input control signal to the driving controller, wherein
the first pixel comprises:
a light emitting element;
a first transistor including a control electrode connected to a first node, a first electrode connected to a second node and a second electrode connected to a third node, the first transistor being configured to transmit a driving current to the light emitting element;
a second transistor configured to apply a data voltage of the first pixel to the first node;
a first capacitor including a first electrode connected to the first node and a second electrode connected to the third node; and
a second capacitor including a first electrode connected to the third node and a second electrode configured to receive a first power voltage, and
the second pixel comprises:
a light emitting element;
a first transistor including a control electrode connected to a first node, a first electrode connected to a second node and a second electrode connected to a third node, the first transistor being configured to transmit a driving current to the light emitting element;
a second transistor configured to apply a data voltage of the second pixel to the first node;
a first capacitor including a first electrode connected to the first node and a second electrode connected to the third node; and
a second capacitor including a first electrode connected to the third node and a second electrode configured to receive a voltage different from the first power voltage, and
the first power voltage is a driving voltage of each of the first pixel and the second pixel for generating the driving current.
